(19) United States
(12) Patent Application Publication
(10) Pub. No.: US 2003/0178620 A1
(43) Pub. Date: Sep. 25, 2003

(54) Organic rectifier, circuit, rfid tag and use of an organic rectifier

(76) Inventors: Adolf Bernds, Baiersdorf (DE); wolfgang Clemens, Puschendorf (DE); Walter Fix, F?uuml;rth (DE); Markus Lorenz, N?uuml;rnberg (DE); Henning Rost, Erlangen (DE)

Correspondence Address: YOUNG & THOMPSON, 745 SOUTH 23RD STREET 2ND FLOOR, ARLINGTON, VA, 22202

(21) Appl. No.: 10/380,113

(22) PCT Filed: Sep. 3, 2001
(86) PCT No.: PCT/DE01/03369

(30) Foreign Application Priority Data
Sep. 11, 2000 (DE) 100 44 842.9

(51) Int. Cl. H01L 35/24

(52) U.S. Cl. 257/40

(57) ABSTRACT

The invention relates to an organic rectifier, for example, one via which the power supply of an organic integrated switching circuit (plastic integrated circuit) occurs. The organic rectifier is characterized by comprising organic conductive and/or semiconductive material.

The invention relates to an organic rectifier, for example one via which power is supplied to an organic integrated circuit (plastic integrated circuit).

Organic integrated circuits based on organic field effect transistors (OFETs) are used for high-volume microelectronics applications and throw-away products such as contactless readable identification and product tags (RFID tags: radio frequency identification tags), where the excellent operating characteristics of silicon technology can be sacrificed in favor of guaranteeing mechanical flexibility and very low manufacturing costs. The components such as electronic barcodes are typically single-use products. Power is supplied to these systems via an antenna which receives electromagnetic radiation from a base station and/or a transmitter and converts it into alternating current.

WO 99/30432 discloses how at least one diode is used to convert the alternating current into direct current. This diode consists of a specially wired transistor (cf. FIG. 2 of relevant patent application). This arrangement ensures that the frequency which can be received by the diode is limited, as the organic transistors, which are used as rectifiers here, generally switch much more slowly (<100 kHz) than the transmitting frequency of the corresponding base stations (typically a radio frequency of approximately 13 MHz)

This means that it is necessary, for optimized operation of an RFID tag system, to provide frequency matching, so to speak, via a hybrid solution whereby an organic integrated circuit is coupled to an inorganic silicon diode.

This coupling of two technologies has several disadvantages at every stage of the RFID tag system, ranging from manufacturing costs, to processibility and maintenance, to disposal.

The object of the invention is therefore to improve the prior art with a view to creating a rectifier from essentially organic materials and an RFID tag comprising several organic field effect transistors, having a diode which can rectify radio frequencies. The object of the invention is additionally to specify several possible applications for an organic rectifier.

The invention relates to a rectifier based on :at least one organic diode and having at least one conductive and one semiconducting layer, at least one of the two layers comprising conductive and/or semiconducting organic material. The invention additionally relates to a circuit in which an organic rectifier is integrated. The invention further relates to the use of an organic rectifier and finally to another organic RFID tag with an integrated organic rectifier.

“Integrated” here means that the rectifier is an integral part of the integrated circuit.

In the “organic rectifier” according to the invention, at least one of the p/n-doped conductive layers of a conventional pn semiconductor diode is supplemented and/or replaced by an organic conductive material. Likewise in the case of a conventional metal/semiconductor diode (Schottky diode) at least one layer can be replaced by an organic layer. Preferably the two conductive layers are replaced by organic conductive material in both diodes.

All circuits incorporating rectifiers based on the anode/n-doped layer/PN junction layer/p-doped layer/cathode principle or on the metallic conductor/semiconductor principle can be replaced by said organic rectifiers.

A rectifier can comprise a single diode only, several diodes and/or additionally have a capacitor.

Although the invention focuses on using the organic diode as a rectifier for an ID tag and/or an RFID tag, it should not be limited to this application.

Preferably the rectifier incorporates a capacitor for smoothing the voltage applied to the rectifier in pulsating form. For this purpose known circuits in which e.g. a capacitor C is connected in parallel with a load resistor are used.

The switching frequency of the rectifier can be set by selecting the size of the capacitive surface area of the rectifier. A dimension permitting the highest possible switching frequency (e.g. in the MHz range) is preferably selected. This can be achieved e.g. by a thick intermediate layer which reduces the capacitance. At the same time, however, the capacitive surface is designed to be suitable for mass production and to ensure a sufficient current flow.

Likewise conceivable is the connection of a rectifier bridge with charging capacitor and/or load resistor, particularly for removing larger direct currents.

The organic rectifier consists of at least two layers, but can also incorporate additional layers for optimization (e.g. to match the work function). For example, an undoped semiconducting layer can be inserted which reduces the capacitance and therefore permits higher frequencies.

Such circuits are known from text books.

In this context, the term “organic material” encompasses all types of organic, metal-organic and/or inorganic plastics. It covers all types of material except for the semiconductors used for conventional diodes (germanium, silicon) and the typical metallic conductors. It is therefore not intended to restrict the term “organic material” to carbon-containing material in any dogmatic sense, rather having in mind also the widespread use of e.g. silicones. Furthermore, the term shall not imply any limitation to polymers or oligomeric materials, the use of “small molecules” also being quite conceivable.

Materials such as polyaniline (PANI), or PEDOT (polyethylenedioxythiophene) can be used as the organic conductive materials. Materials such as polythiophene or polyfluorene are suitable for the organic semiconducting materials.

The organic semiconducting or semiconducting material is matched to the organic semiconducting material in such a way that the rectifier structure produces a typical diode characteristic when a voltage is applied, the current flowing in one direction only and the other direction being largely non-conducting.

The invention will now be explained with reference to a figure.

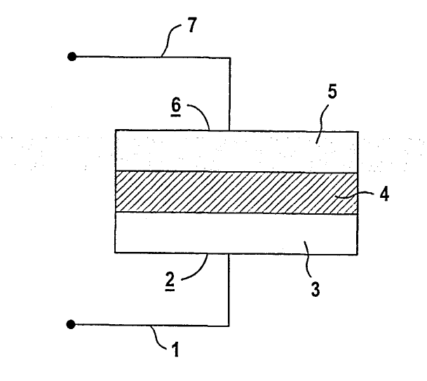

FIG. 1 shows a schematic diagram of a rectifier.

FIG. 1 shows a rectifier diode in schematic form. It can be seen that alternating current flows through the lead 1 to the cathode 2. When positive voltage is present, electrons pass from the cathode 2 to the organic conductor material 3 and from there to the semiconducting material 4 and through the conductor material layer 5 to the anode 6. The lead 7 then picks up the electrons. When negative voltage is applied, the rectifier shuts down and the semiconducting material blocks the flow of current.

The semiconductor layer must not be too thin, e.g. 50 to 2000 nm thick. The layer thickness of the conductor materials is not so relevant. In order to have a connection contact offering as low resistance as possible, they must be thicker than the semiconductor layers.

The setup described in FIG. 1 only illustrates a simple example. It can be optimized by adding further layers (e.g. to match the work function), the conductor materials having to be matched to the semiconductor material in such a way that the structure produces a diode characteristic, in other words, so that the current flows in one direction only and the other direction is largely non-conducting. To achieve this, the ratio of the currents must be at least 10/1, but if possible >10⁵/1. In the forward direction, virtually the entire available current must flow even when extremely small voltages are applied.

The organic rectifier must be of such small dimensions (capacitive surface area) that a switching frequency of at least 10 kHz is achieved, but if possible in the MHz range. A typical frequency for RFID tags is 13.56 MHz, this being preferably achieved using the rectifier.

Organic rectifiers are highly versatile. They can be used, for example, in

integrated circuits generally

ident systems (ident tags, RFID (radio frequency ident tags), e.g. for

electronic barcode

electronic tickets

plagiarism protection

product information

sensors and

organic displays with integrated electronics.

1. Rectifier based on at least one organic diode and incorporating at least one conductive and one semiconducting layer, at least one of the conductive layers being essentially made of organic material.

2. Rectifier according to claim 1, wherein the semiconducting layer is essentially made of organic material.

3. Rectifier according to one of the preceding claims, wherein one conducting layer is made of metal.

4. Rectifier according to one of the preceding claims, wherein one semiconducting layer is essentially made of soluble polymer.

5. Rectifier according to one of the preceding claims and having a switching frequency in the megahertz range.

6. Rectifier according to one of the preceding claims and having a thick intermediate layer.

7. Circuit with a rectifier according to one of claims 1 to 6 and incorporating a capacitor.

8. Circuit according to claim 7 incorporating a rectifier bridge with charging capacitor and/or load resistor.

9. Use of a rectifier and/or circuit according to one of the preceding claims in electronics and/or microelectronics, such as in conjunction with an organic field effect transistor, a sensor, a display and/or a radio frequency identification tag.
